(19) United States
(12) Patent Application Publication
(10) Pub. No.: US 2025/0306077 A1
(43) Pub. Date: Oct. 2, 2025

(54) SOLID-STATE PULSE GENERATING SYSTEM AND THE CONTROL SYSTEM THEREOF

(71) Applicant: The Hong Kong University of Science and Technology, Hong Kong (CN)

(72) Inventors: Jing CHEN, Hong Kong (CN); Jiahui SUN, Hong Kong (CN); Ji SHU, Hong Kong (CN)

(21) Appl. No.: 19/084,796

(22) Filed: Mar. 20, 2025

Related U.S. Application Data
(60) Provisional application No. 63/570,239, filed on Mar. 27, 2024.

(51) Int. Cl. G01R 31/00; G01R 31/319

(52) U.S. Cl. CPC G01R 31/001; G01R 31/31924

(57) ABSTRACT

Provided herewith is a new bimodal solid-state pulse generating system to generate ESD pulses for the ESD test, and narrow high-speed pulses for high-speed pulsed I-V characterization of electronic components. Accordingly, the bimodal solid-state pulse generating system is capable of operating in a dual-polarity electrostatic discharge testing mode and a pulsed I-V characterization mode respectively. In comparison with the conventional toxic mechanical mercury relay, not only is the new system display equivalent or superior performance in terms of high-speed pulse generation, but the new system also eliminates the drawbacks of the toxic mechanical mercury relays on the maximum operating cycles, and their toxicity and environmental hazard.

### CROSS-REFERENCE TO RELEVANT APPLICATIONS

The present application claims priority from a U.S. provisional patent application Ser. No. 63/570,239 filed Mar. 27, 2024, and the disclosure of which are incorporated by reference in their entirety.

### FIELD OF THE INVENTION

The present invention relates to solid-state pulse generating system. More specifically, the solid-state pulse generating system of the present invention is bimodal, can be used for both electrostatic discharge (ESD) test and high-speed pulsed I-V characterization, and do not share the shortcomings of using conventional toxic mercury mechanical relays.

### BACKGROUND OF THE INVENTION

In events of sudden releases of static electricity, referred to as electrostatic discharge (ESD) events, overcurrent or overvoltage stress may be induced to electronic components, which may in turn inflict damage and cause failure of electronic devices. As such, ESD simulation is required for electronic components to characterize their ESD robustness, such that the electronic components are ensured to be capable of withstanding ESD events without being damaged.

On the other hand, pulsed I-V characterization is a test for analyzing the electric behavior of an electronic component when exposed to high-speed voltage and current pulses. This test is carried out with precisely controlled electric pulses such that they are fast enough to capture transient effects without causing excess heating or damage to the device.

Given the fact that modern semiconductor devices, e.g. 5G chips and RF circuits operate under fast transient conditions, ESD simulation and pulsed I-V characterization are both crucial for simulation of real-world stress conditions on these devices to evaluate their safety and performances.

However, conventionally the ESD test and pulsed I-V characterization processes are conducted on different equipment. Also, toxic mercury relays are essential for the ESD simulator, which is based on the transmission line pulse (TLP) generating system. The toxic mercury relays are based on mechanical contact, thereby introducing limitations on the maximum switching cycles due to contact degradation upon every switching cycle. The toxicity of the mercury also imposes health threats to the operating technicians, and environmental hazard upon disposure.

Therefore, there is a need in the art to integrate the ESD test and pulsed I-V characterization into a single pulse generating system, and also preferably to develop a substitute to toxic mercury mechanical relays to tackle the problems of toxicity and limited lifespan in terms of maximum switching cycles. The present invention addresses this need.

### SUMMARY OF THE INVENTION

In response to the above-mentioned challenges and demands, as described below, the present invention provides bimodal solid-state pulse generation system for dual-polarity electrostatic discharge test and high-speed I-V characterization of electronic devices, which is capable of operating in a first dual-polarity electrostatic discharge testing mode and a second pulsed I-V characterization mode.

The bimodal solid-state pulse generation system comprises (i) a power supply unit comprising a first positive power supply, and a first control switch connected to the first positive power supply in series, and a second negative power supply connected to the first positive power supply and the first control switch in parallel, and a second control switch connected to the second negative power supply in series; (ii) a pulse generating unit comprising a first resistor, a first capacitor, and one or more first bidirectional solid-state semiconductor power components connected in series or in parallel; and (iii) a pulse discharging unit comprising a second resistor, a third control switch, and one or more second bidirectional solid-state semiconductor power components connected in series or in parallel. The electronic device under test is connected between the pulse generating unit and the pulse discharging unit.

In an embodiment, the one or more first and second bidirectional solid-state semiconductor power components capable of bidirectional voltage blocking are bidirectional semiconductor power devices; or a pair of unidirectional semiconductor power devices that are connected in series and in reverse directions.

In a further embodiment, the pair of unidirectional semiconductor power devices are selected from cascode power devices, devices with symmetric PN-PN structures, hybrid Schottky-PN diodes, gallium nitride (GaN) high electron mobility transistors (HEMTs) with voltage rating of no less than 400V, or silicon carbide (SiC) metal oxide semiconductor field effect transistors (MOSFETs) with voltage rating of no less than 400V.

In another embodiment, the first resistor has an adjustable resistance in a range of 0 to 2 kω.

In other embodiment, the first capacitor has an adjustable capacitance in a range of 0 to 5000 pF.

In yet another embodiment, the third control switch has a parasitic capacitance of no more than 10 pF in OFF state.

In yet other embodiment, the first and second bidirectional solid-state semiconductor power components have lifespans of more than 10 billion switching cycles.

In another embodiment, both the rise time and the fall time of the generated pulse in the second pulsed I-V characterized mode are no more than 10 ns.

In a further embodiment, under the first dual-polarity ESD test mode, the system conducts the ESD test with the following procedures: (i) activating the third control switch S3 and the second bidirectional solid-state semiconductor power component S4 to initiate the ESD test; (ii) determining an ESD polarity to classify the test as a positive ESD test or a negative ESD test; (iii) activating the first control switch S11 to charge the first capacitor C1 and deactivating the first control switch S11 after the first capacitor C1 is charged for a positive ESD test, or activating the second control switch S1 to charge the capacitor C1 and deactivating the second control switch S1 after the capacitor C1 is charged for a negative ESD test; (iv) deactivating the third control switch S3; (v) activating the first bidirectional solid-state semiconductor power component S2 to generate an ESD pulse onto the DUT; (vi) activating the third control switch S3 to discharge the system after pulse delivery; (vii) deactivating the third control switch S3 and the first and second bidirectional solid-state semiconductor power components S2 and S4 to reset the system; (viii) determining whether another ESD pulse is required; and (ix) repeating the above steps (iii)-(viii) accordingly if another ESD pulse is determined to be required, or terminating the ESD test if no further ESD pulses are determined to be required.

In another further embodiment, under the second pulsed I-V characterization mode, the system conducts the pulsed I-V characterization with the following procedures: (i) activating the third control switch S3 to initiate the pulsed I-V characterization; (ii) determining a test polarity to classify the test as a positive I-V characterization or a negative I-V characterization; (iii) activating the first control switch S11 to charge the first capacitor C1 while maintaining the second control switch S1 in an OFF state, and deactivating the first control switch S11 after the first capacitor C1 is charged for a positive I-V characterization, or activating the second control switch S1 to charge the capacitor C1 while maintaining the first control switch S11 in an OFF state, and deactivating the second control switch S1 after the capacitor C1 is charged for a negative I-D characterization; (iv) activating the first bidirectional solid-state semiconductor power component S2 to generate a pulse onto the DUT; (v) deactivating the first bidirectional solid-state semiconductor power component S2 and activating the second bidirectional solid-state semiconductor power component S4 to discharge the DUT; (vi) deactivating the second bidirectional solid-state semiconductor power component S4 to complete the pulse cycle; (vii) determining whether another pulse is required and repeat the above steps (iii)-(vii) if another pulse is required until no further pulses are required; (viii) activating the third control switch S3 and the first bidirectional solid-state semiconductor power component S2 in sequence to charge the system; (ix) deactivating all control switches and bidirectional solid-state semiconductor power components to reset the system; and (x) terminating the pulsed I-V characterization process.

### BRIEF DESCRIPTION OF THE DRAWINGS

Embodiments of the invention are described in more details hereinafter with reference to the drawings, in which:

FIG. 1 shows the bimodal solid-state pulse generating system of the present invention.

FIG. 2 shows the configuration of the positive pulse generating mode of the system of the present invention.

FIG. 3 shows the configuration of the negative pulse generating mode of the system of the present invention.

FIG. 4 is a flowchart of the procedures of the ESD test control system of the pulse generating system in ESD test mode.

FIG. 5 is a flowchart of the procedures of the pulsed I-V test control system of the pulse generating system in pulsed I-V characterization mode.

### DETAILED DESCRIPTION

The invention relates to a bimodal solid-state pulse generating system to generate ESD pulses for the ESD test, and narrow high-speed pulses for high-speed pulsed I-V characterization of electronic components. Accordingly, the bimodal solid-state pulse generating system is capable of operating in a dual-polarity electrostatic discharge testing mode and a pulsed I-V characterization mode respectively.

As described above, ESD robustness is a crucial measurement to ensure an electronic component to withstand and function after exposure to unexpected electrostatic discharges, and pulse I-V tests is a characterization of an electronic component during controlled high-speed electric pulses. Conventionally, these two measurements or characterization is carried out with different setups. While modern semiconductor devices like 5G chips, power semiconductors, RF and high-speed digital devices are developed to operate under fast transient conditions and are increasingly vulnerable due to the general decrease in size, both ESD robustness and pulsed I-V tests are crucial for characterization for safety and performance, and thus an integrated setup for sequential testing is generally favored over testing on separate setups.

For ESD tests, high-speed high-voltage generation is generally required, therefore conventional candidates for the ESD simulator are the mercury relay or the gas-filled relay, in which the mercury or ionized gases (e.g. SF6) can still carry current when the mechanical contact is bouncing during the switching process. As a result, the false turn-on/off problems induced by the mechanical contact bouncing of the relay can be solved.

However, both relays are based on mechanical contact, which introduces limitations on the maximum switching cycles due to the contact degradation in every switching cycle. Additionally, the intrinsic toxicity of the mercury component in the mercury relay and the chemically hazardous ionized gases in the gas-filled relay inevitably imposes environmental risks during handling and, in particular, disposal.

On the other hand, the pulsed I-V characterization process requires high-speed high-current pulses, which is previously achievably only through charged transmission lines. However, the transmission line pulse (TLP) I-V system thus set up is bulky and heavy, hence discounting the ease of application of pulsed I-V characterization. In addition, toxic mercury relays are also essential in TLP I-V systems, therefore the same drawbacks as discussed above are yet to be solved.

Therefore, the present invention solves the above issues by integrating the functionalities of ESD test and pulsed I-V characterization into a single bimodal system. Also, the reliance on mercury relays is eliminated through replacement by bidirectional solid-state semiconductor power components.

Further discussions on the details of the system setup and operation are as below:

### EXAMPLES

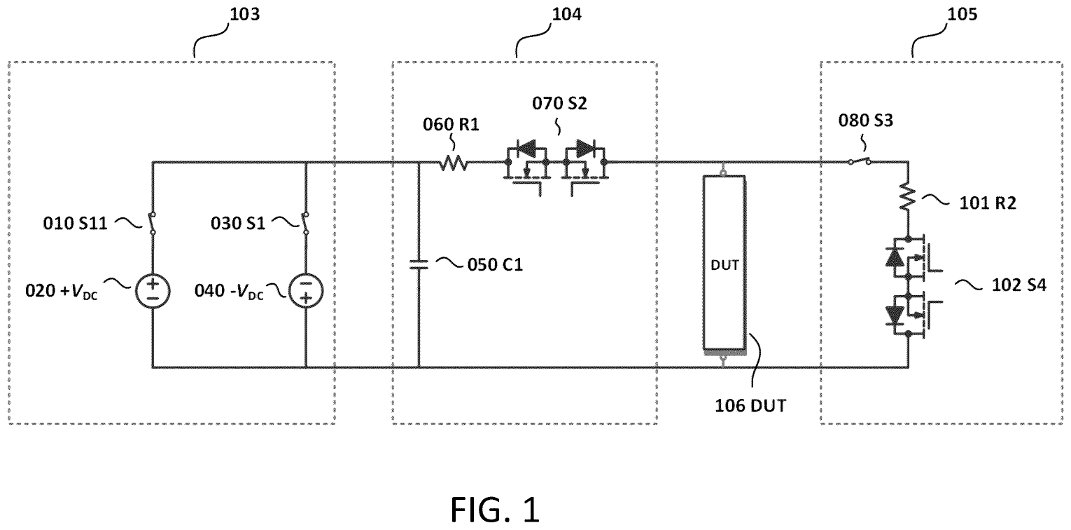

Referring to FIG. 1, which shows the configuration of the proposed solid-state pulse generating system, the bimodal solid-state pulse generating system of the present invention includes three main units, which are the power supply unit 103, the pulse generating unit 104, and the pulse discharging unit 105. The device under test (DUT) 106 is connected between the pulse generating unit 104 and the pulse discharging unit 105.

The power supply unit 103 consists of a first positive power supply +V_{DC} 020, a second negative power supply −V_{DC} 040, a first control switch S11 010 connected in series with the first positive power supply +V_{DC} 020, and a second control switch S1 030 connected in series with the second negative power supply −V_{DC} 040.

The pulse generating unit 104 consists of three series-connected components, which are a first capacitor C1 050, a first resistor R1 060, and a first bidirectional solid-state semiconductor power component S2 070. The pulse discharging unit 105 consists of a third control switch S3 080, a second resistor 101, and a second bidirectional solid-state semiconductor power component S4 102. The location of each element in each unit can vary, so long as the basic function are not affected.

In one preferred embodiment of the pulse generating system, several pulse generating units with different capacitor and resistor values and semiconductor power device with different current and voltage ratings are designed. As such, different pulse generating unit can be used in the pulse generating system to comply with different requirements of different ESD test standards and different operation modes, i.e. the ESD test mode and pulse I-V characterization mode.

In the ESD test operation mode, the resistance of R1 060 and the capacitance of C1 050 is determined by the specific ESD standard. However, for different ESD standards, the values of capacitor C1 050 and the resistor R1 060 are respectively adjustable (for example, in the range of 0 to 2 kω and 0 to 5000 pF, respectively), which enables flexible adaptation to different test requirements while simultaneously ensuring functionality and configuration stability. In addition, in the high-speed high-current pulsed I-V characterization operation mode, large capacitor value for C1 050 and low resistance value for R1 060 are required for short pulse rising edge.

In the high-speed high-current pulsed I-V characterization operation mode, the resistance of R1 060 and capacitance of C1 050 in the pulse generating unit 104 can be selected to ensure that the switching oscillation of the high-speed narrow pulses are suppressed within an acceptable level. Meanwhile, a large capacitor C1 050 is preferred for the ability to realize multiple pulses, and a small resistance R1 060 is preferred to ensure the pulse rising edge is fast. The resistance R2 101 should be selected to ensure the pulse discharging process is fast with suppressed oscillations, thereby high-speed narrow pulses can be realized.

The bimodal solid-state pulse generating system can generate both positive and negative pulses for both dual-polarity ESD test and pulsed I-V characterization. The power supply unit 103 consists of both positive polarity and negative polarity power supply. The power semiconductor devices S2 070 and S4 102 are bidirectional semiconductor devices that can block voltage in both directions.

The first and second bidirectional solid-state semiconductor power components of the pulse generating system, i.e., S2 070 and S4 102, encompass a range of options. Particularly, the bidirectionality of the solid-state semiconductor power components is achieved through the use of a bidirectional solid-state semiconductor power devices with bidirectional voltage blocking capabilities, or a pair of unidirectional solid-state semiconductor power devices connected in series but in opposition directions.

Bidirectional solid-state semiconductor power device with bidirectional voltage blocking capabilities include but are not limited to high-voltage (no lower than 400 V) gallium nitride (GaN) high-electron-mobility transistors (HEMTs), high-voltage (no lower than 400V) silicon carbide (SiC) metal-oxide-semiconductor field-effect transistors (MOSFETs), cascode power devices, devices with symmetric PN-PN structures, and hybrid Schottky-PN diodes.

Cascode power devices as used in this specification is defined as the common low-voltage and high-voltage pair configuration. For example, the cascode power devices used as the solid-state semiconductor power component can be a cascode power device based on the combination of a high-voltage normally-on GaN HEMT and a low-voltage silicon (Si) MOSFET, cascode power device based on the combination of the high-voltage SiC junction field effect transistor (JFET) and a low-voltage Si MOSFET, as well as cascode power device based on the combination of the high-voltage SiC junction field effect transistor (JFET) and a low-voltage GaN HEMT.

On the other hand, hybrid Schottky-PN diodes as used in this specification is defined as hybrid diodes combining the advantages of a low-forward voltage fast-switching Schotttky diode and a high-voltage blocking low-leakage current PN diode. For example, a Junction Barrier Schottky (JBS) diode with embedded p+regions, or a Merged PiN Schottky (MPS) diode with more extend PiN regions merged with the Schottky diode are both applicable.

Power semiconductor devices having symmetric PN-PN structures are inherently capable to block voltage in both directions, with examples being gate commutated thyristors (GCTs) and bidirectional IGBTs (BIGBTs).

Additionally, the third control switch S3 080 is selected to have a small parasitic capacitance at OFF state, specifically below 10 pF. This low parasitic capacitance is particular important in reducing charge injection, reducing RC time constant to achieve sharper pulse edges for the pulsed I-V characterization, and preventing signal distortion due to overshoot, undershoot or prolonged settling times.

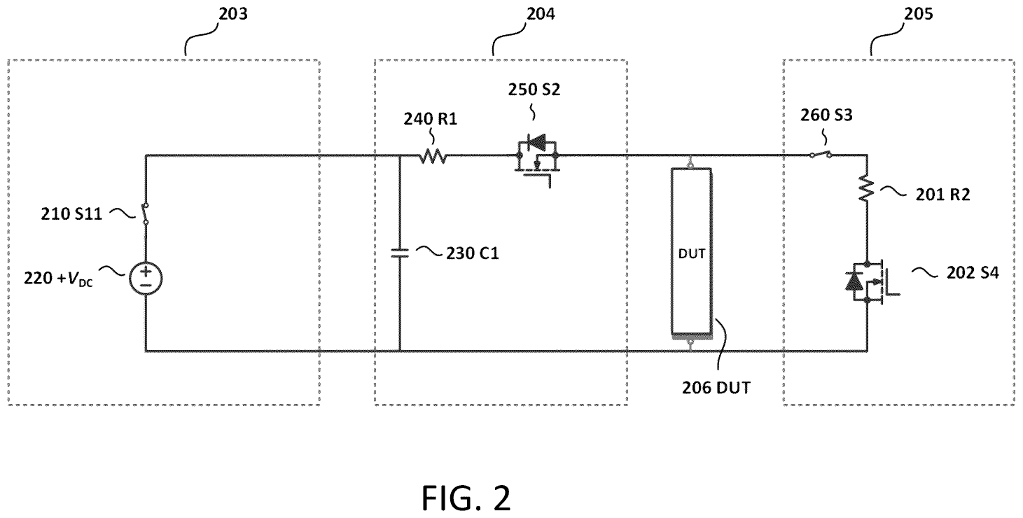

Referring to FIG. 2, an embodiment of the pulse generating system is shown, in which the system is only able to generate positive pulses for positive ESD test and positive pulsed I-V characterization. Therefore, a negative power supply is no longer necessary, and only unidirectional power semiconductor devices are needed in S2 250 and S4 202.

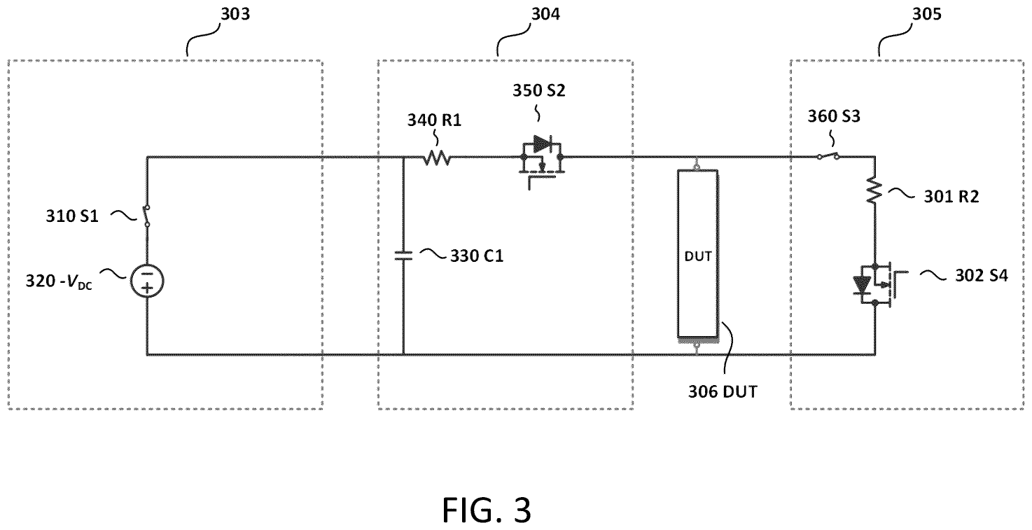

FIG. 3 shows another embodiment of the pulse generating system, in which the system is only able to generate negative pulses for negative ESD tests and negative pulsed I-V characterization. Therefore, a positive power supply is no longer necessary, and only unidirectional power semiconductor devices are needed in S2 350 and S4 302.

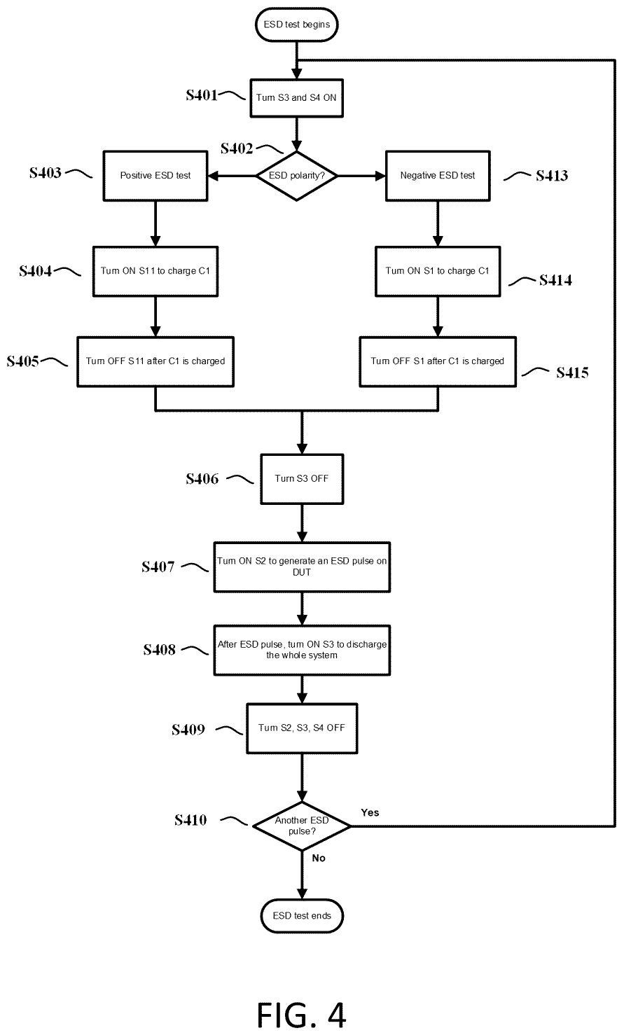

FIG. 4 shows the flowchart of the ESD test control system of the solid-state pulse generating system when it operates in ESD test mode. At the beginning of the ESD test, the S3 and S4 are turned ON to short the device under test (DUT), thereby preventing the potential stress before the ESD event. Then, the capacitor C1 is charged by the power supply by turning ON the series-connected control switch. If a positive ESD test is needed, turn ON S11. If a negative ESD test is needed, turn ON S1. After the capacitor C1 is charged up by the power supply, the control switch (S1 or S11) is turned OFF again. After the charging process of C1, S3 is turned OFF. After S3 is turned OFF, the power device S2 is turned ON to impose an ESD pulse on DUT. After the ESD event, S3 is turned ON to discharge the whole system, after which all switches and devices are turned OFF, restoring the initial state of the system. Subsequently, the control system will determine whether another ESD test is needed. If yes, the control system will go back to step S401, turning ON S3 and S4, and repeating the whole process again. If no, the ESD test ends.

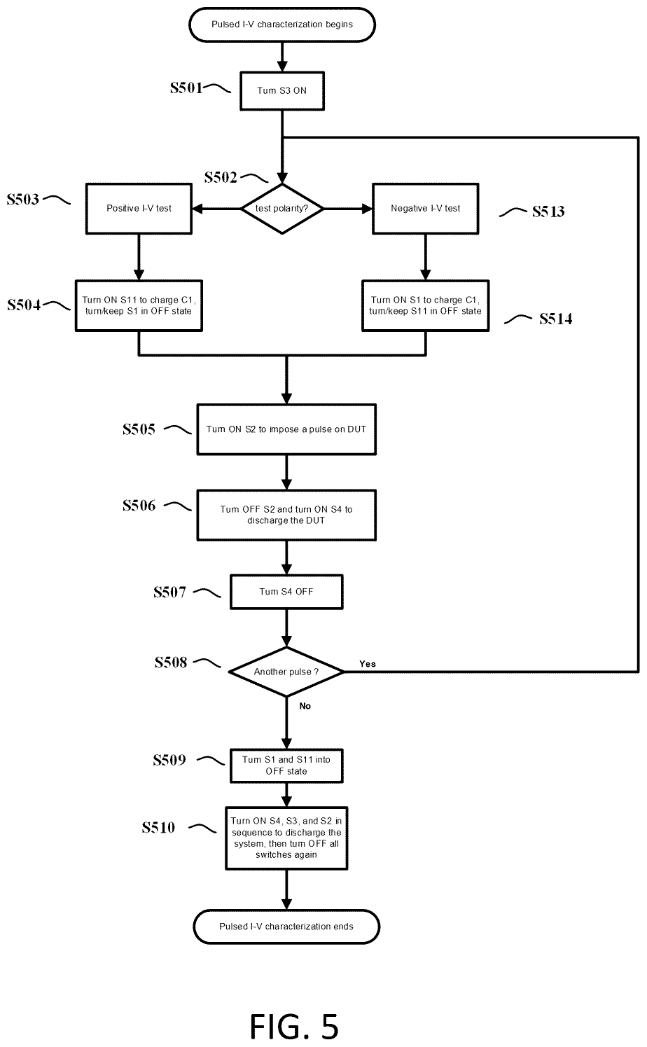

FIG. 5 shows the pulsed I-V test control system of the solid-state pulse generating system when it operates in pulsed I-V characterization mode. At the beginning of the pulsed I-V characterization, the S3 is turned ON. Then, the capacitor C1 is charged by the power supply by turning ON the series-connected control switch. If positive pulsed I-V characterization is needed, turn ON S11. If negative pulsed I-V characterization is needed, turn ON S1. After the charging process of C1, the power device S2 is turned ON to impose a pulse on DUT. After the predetermined pulse duration, the power device S2 is turned OFF, and S4 is turned ON to discharge the pulse. Then S4 is turned OFF again, and the system will determine whether another pulse is needed. If yes, the control system will go to step S502. First, the test polarity will be determined, and the following steps will be repeated. If no, the S1 and S11 will be turned OFF. Then, S4, S3, and S2 will be turned ON in sequence to discharge the whole system. Then all semiconductor devices and switches are turned OFF, restoring the initial state of the pulse generating system. The pulsed I-V characterization ends.

Throughout this specification, unless the context requires otherwise, the word “comprise” or variations such as “comprises” or “comprising”, will be understood to imply the inclusion of a stated integer or group of integers but not the exclusion of any other integer or group of integers. It is also noted that in this disclosure and particularly in the claims and/or paragraphs, terms such as “comprises”, “comprised”, “comprising” and the like can have the meaning attributed to it in U.S. Patent law; e.g., they allow for elements not explicitly recited, but exclude elements that are found in the prior art or that affect a basic or novel characteristic of the present invention.

Furthermore, throughout the specification and claims, unless the context requires otherwise, the word “include” or variations such as “includes” or “including”, will be understood to imply the inclusion of a stated integer or group of integers but not the exclusion of any other integer or group of integers.

References in the specification to “one embodiment”, “an embodiment”, “an example embodiment”, etc., indicate that the embodiment described can include a particular feature, structure, or characteristic, but every embodiment may not necessarily include the particular feature, structure, or characteristic. Moreover, such phrases are not necessarily referring to the same embodiment. Further, when a particular feature, structure, or characteristic is described in connection with an embodiment, it is submitted that it is within the knowledge of one skilled in the art to affect such feature, structure, or characteristic in connection with other embodiments whether or not explicitly described.

Other definitions for selected terms used herein may be found within the detailed description of the present invention and apply throughout. Unless otherwise defined, all other technical terms used herein have the same meaning as commonly understood to one of ordinary skill in the art to which the present invention belongs.

It will be appreciated by those skilled in the art, in view of these teachings, that alternative embodiments may be implemented without undue experimentation or deviation from the spirit or scope of the invention, as set forth in the appended claims. This invention is to be limited only by the following claims, which include all such embodiments and modifications when viewed in conjunction with the above specification and accompanying drawings.

1. A bimodal solid-state pulse generation system for dual-polarity electrostatic discharge test and high-speed pulsed I-V characterization of electronic devices, comprising :
a power supply unit comprising:
a first positive power supply, and a first control switch connected to the first positive power supply in series; and
a second negative power supply connected to the first positive power supply and the first control switch in parallel, and a second control switch connected to the second negative power supply in series;
a pulse generating unit comprising:
a first resistor,
a first capacitor, and
one or more first bidirectional solid-state semiconductor power components connected in series or in parallel; and
a pulse discharging unit comprising:
a second resistor,
a third control switch, and
one or more second bidirectional solid-state semiconductor power components connected in series or in parallel;
wherein the electronic device under test is connected between the pulse generating unit and the pulse discharging unit; and
wherein the bimodal solid-state pulse generation system is capable of operating in a first dual-polarity electrostatic discharge testing mode and a second pulsed I-V characterization mode.

2. The system of claim 1, wherein the one or more first and second bidirectional solid-state semiconductor power components are jointly or independently selected from a bidirectional semiconductor power unit capable of voltage blocking; or a pair of unidirectional semiconductor power units connected in series and in reverse directions.

3. The system of claim 2, wherein the unidirectional or bidirectional semiconductor power units for voltage blocking is selected from cascode power devices, devices with symmetric PN-PN structures, hybrid Schottky-PN diodes, gallium nitride (GaN) high electron mobility transistors (HEMTs) with voltage rating of no less than 400V, or silicon carbide (SiC) metal oxide semiconductor field effect transistors (MOSFETs) with voltage rating of no less than 400V.

4. The system of claim 1, wherein the first resistor has an adjustable resistance in a range of 0 to 3 kω.

5. The system of claim 1, wherein the first capacitor has an adjustable capacitance in a range of 0 to 5000 pF.

6. The system of claim 1, wherein the third control switch has a parasitic capacitance of no more than 10 pF in OFF state.

7. The system of claim 1, wherein the first and second bidirectional solid-state semiconductor power components have lifespans of more than 10 billion switching cycles.

8. The system of claim 1, wherein both the rise time and the fall time of the generated pulse in the second pulsed I-V characterized mode are no more than 10 ns.

9. A method of conducting an electrostatic discharge (ESD) test on a device under test (DUT) using the system of claim 1 in the first dual-polarity electrostatic discharge testing mode, the method comprising:
activating the third control switch S3 and the second bidirectional solid-state semiconductor power component S4 to initiate the ESD test;
determining an ESD polarity to classify the test as a positive ESD test or a negative ESD test;
activating the first control switch S11 to charge the first capacitor C1 and deactivating the first control switch S11 after the first capacitor C1 is charged for a positive ESD test, or activating the second control switch S1 to charge the capacitor C1 and deactivating the second control switch S1 after the capacitor C1 is charged for a negative ESD test;
deactivating the third control switch S3;
activating the first bidirectional solid-state semiconductor power component S2 to generate an ESD pulse onto the DUT;
activating the third control switch S3 to discharge the system after pulse delivery;
deactivating the third control switch S3 and the first and second bidirectional solid-state semiconductor power components S2 and S4 to reset the system;
determining whether another ESD pulse is required; and
repeating the above steps accordingly if another ESD pulse is determined to be required, or terminating the ESD test if no further ESD pulses are determined to be required.

10. A method of conducting a pulsed I-V characterization on a device under test (DUT) using the system of claim 1 in the second pulsed I-V characterization mode, the method comprising:
activating the third control switch S3 to initiate the pulsed I-V characterization;
determining a test polarity to classify the test as a positive I-V characterization or a negative I-V characterization;
activating the first control switch S11 to charge the first capacitor C1 while maintaining the second control switch S1 in an OFF state, and deactivating the first control switch S11 after the first capacitor C1 is charged for a positive I-V characterization, or activating the second control switch S1 to charge the capacitor C1 while maintaining the first control switch S11 in an OFF state, and deactivating the second control switch S1 after the capacitor C1 is charged for a negative I-D characterization;
activating the first bidirectional solid-state semiconductor power component S2 to generate a pulse onto the DUT;
deactivating the first bidirectional solid-state semiconductor power component S2 and activating the second bidirectional solid-state semiconductor power component S4 to discharge the DUT;
deactivating the second bidirectional solid-state semiconductor power component S4 to complete the pulse cycle;
determining whether another pulse is required and repeat the above steps if another pulse is required until no further pulses are required;
activating the third control switch S3 and the first bidirectional solid-state semiconductor power component S2 in sequence to charge the system;
deactivating all control switches and bidirectional solid-state semiconductor power components to reset the system; and
terminating the pulsed I-V characterization process.
